(19) United States
(12) Patent Application Publication
(10) Pub. No.: US 2026/0142129 A1
(43) Pub. Date: May 21, 2026

(54) GAS, GAS COMBINATION, ETCHING METHOD AND EQUIPMENT FOR PLASMA ETCHING

(71) Applicant: Advanced Micro-Fabrication Equipment Inc. China, Shanghai (CN)

(72) Inventors: Kai ZHANG, Shanghai (CN); Weina XU, Shanghai (CN); Jianqiu HOU, Shanghai (CN); Ziyang WU, Shanghai (CN); Yichuan ZHANG, Shanghai (CN)

(21) Appl. No.: 19/450,396

(22) Filed: Jan. 15, 2026

Related U.S. Application Data
(63) Continuation of application No. PCT/CN2024/102261, filed on Jun. 28, 2024.

(30) Foreign Application Priority Data
Jul. 20, 2023 (CN) 202310904642.3

(51) Int. Cl. H01J 37/32; H10P 50/00; H10P 50/26; H10P 50/28

(52) U.S. Cl. CPC H01J 37/32449; H10P 50/268; H10P 50/283; H10P 50/71; H10P 50/73; H01J 2237/334

(57) ABSTRACT

Provided in the present disclosure are a gas, a gas combination for plasma etching, an etching method and semiconductor equipment, belonging to the field of plasma etching. In the etching process, one or more of a carbonyl halide, an acyl halide and a carboxylic acid halide are provided as process gases and are excited to form a plasma to etch a layer to be etched, so that the problem of inconsistency between the top and the bottom caused by the fact that the etching rate of the bottom is quite different from the etching rate of the middle part when etching is performed to a certain extent to form a high-aspect-ratio hole or groove is solved, the morphology of high-aspect-ratio etching is significantly improved, the collimation is ensured, and the effectiveness of the semiconductor structure is improved.

### CROSS-REFERENCE TO RELATED APPLICATION

This application is a Continuation application of International Patent Application No. PCT/CN2024/102261, filed on Jun. 28, 2024, which is based on and claims priority to and benefits of Chinese Patent Application No. 202310904642.3, filed with the China National Intellectual Property Administration on Jul. 20, 2023, titled “GAS, GAS COMBINATION, ETCHING METHOD AND EQUIPMENT FOR PLASMA ETCHING.” The above-referenced applications are incorporated herein by reference in their entirety.

### TECHNICAL FIELD

The present disclosure relates to the technical field of plasma etching, and in particular to a gas and a gas combination for plasma etching of a high-aspect-ratio object, an etching method and semiconductor equipment.

### BACKGROUND

Micro-machining of semiconductor wafers or substrates is a well-known technology, which can be used to manufacture, for example, semiconductors, flat panel displays, light-emitting diodes (LED), solar batteries and the like. An important step of the micro-machining is a plasma processing step. The process step is performed inside a reaction chamber, and a process gas is input into the reaction chamber. A radio frequency source is inductively and/or capacitively coupled into the reaction chamber to excite the process gas to form and maintain a plasma.

With the pursuit of Moore's Law, different process technologies and semiconductor structures have been invented. Whether logic chips or memory chips, more and more high-aspect-ratio structures are required to be etched by a plasma technology.

When the etching purpose is to form a high-aspect-ratio structure, the continuous etching of the bottom of the structure becomes difficult gradually, and even if etching is performed to a predetermined depth, a morphological deviation is prone to occur. When the upper and lower dimensions of the high-aspect-ratio structure are inconsistent, or defects such as unevenness and curvature occur in a local area, the electrical conductivity of subsequent devices will be further affected, and in serious cases, the devices will fail.

### SUMMARY

To solve the above technical problems, the present disclosure provides a plasma etching method, including the following steps:

providing a wafer with a layer to be etched and a mask layer above the layer to be etched thereon; and
introducing a first type of gas and a second type of gas and performing excitation to form a plasma to etch a layer to be etched to form a hole or groove,
where the first type of gas includes one or more of a fluorocarbon and a hydrofluorocarbon, and
the second type of gas includes one or more of a carbonyl halide, an acyl halide and a carboxylic acid halide.

Optionally, the carbonyl halide includes a functional group (CO)— in combination with one or two of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

Optionally, the acyl halide includes a functional group (COH)— in combination with one of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

Optionally, the carboxylic acid halide includes a functional group (COOH)— in combination with one of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

Optionally, the second type of gas includes COF₂.

Optionally, the first type of gas includes one or more of CF₄, CHF₃, CH₂F₂, C₂HF₅ and C₃HF₅.

Optionally, the volume of the first type of gas accounts for 30% to 70% of the volume of the total gas, and the volume of the second type of gas accounts for 1% to 30% of the volume of the total gas.

Optionally, the flow rate of the first type of gas ranges from 10 sccm to 300 sccm, and the flow rate of the second type of gas ranges from 5 sccm to 200 sccm.

Optionally, when the first type of gas and the second type of gas are introduced, an auxiliary gas is also introduced, and the auxiliary gas includes one or more of O₂, H₂, NF₃, HBr, WF₆ and Ar.

Optionally, the volume of the auxiliary gas accounts for 10% to 30% of the volume of the total gas.

Optionally, the flow rate of the auxiliary gas ranges from 1 sccm to 200 sccm.

Optionally, the layer to be etched includes SiO₂, Si₃N₄, polycrystalline silicon or an alternating stack of any two of the aforementioned.

Optionally, the aspect ratio of the hole or groove is greater than 40.

Optionally, when the plasma is excited, the frequency of the radio frequency ranges from 13 MHz to 200 MHz, and the power ranges from 1000 W to 30000 W.

Optionally, when the layer to be etched is etched, the temperature of the wafer ranges from −50° C. to 100° C.

Optionally, when the layer to be etched is etched, the gas pressure ranges from 15 mT to 40 mT.

Further, the present disclosure further provides a gas combination for plasma etching, including:
a first type of gas, including one or more of a fluorocarbon and a hydrofluorocarbon;
a second type of gas, including one or more of a carbonyl halide, an acyl halide and a carboxylic acid halide; and
an auxiliary gas, including one or more of O₂, H₂, NF₃, HBr, WF₆ and Ar.

Optionally, the carbonyl halide includes a functional group (CO)— in combination with one or two of F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—; the acyl halide includes a functional group (COH)— in combination with one of F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—; and the carboxylic acid halide includes a functional group (COOH)— in combination with one of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

Optionally, the first type of gas includes one or more of CF₄, CHF₃, CH₂F₂, C₂HF₅ and C₃HF₅.

Further, the present disclosure further provides a plasma etching method, including the following steps:
providing an etching object with a hole or groove structure thereon; and
providing a process gas including COF₂, performing excitation to form a plasma, and continuously etching the hole or groove by applying a bias radio frequency.

Optionally, when the COF₂ is excited into the plasma, the COF₂ can be decomposed into a COF+ group and F—, the COF+ group arrives at the bottom of the hole or groove under the action of the bias radio frequency and performs a chemical reaction with the etching object at the bottom of the hole or groove to generate a volatile product.

Optionally, the lateral etching quantity of the COF+ group at the bottom of the hole or groove is greater than the lateral etching quantity of the COF+ group at the middle part of the hole or groove.

Optionally, the etching object includes SiO₂, Si₃N₄, polycrystalline silicon or an alternating stack of any two of the above.

Optionally, the frequency of the bias radio frequency ranges from 150 kHz to 4 MHz, and the power ranges from 500 W to 10 kW.

Optionally, the plasma etching method further includes the following steps:
providing a wafer with a layer to be etched and a mask layer above the layer to be etched thereon, where the layer to be etched includes SiO₂, Si₃N₄ or an alternating stack of the two; and
providing a process gas including one or more of CF₄, CHF₃, CH₂F₂, C₂HF₅ and C₃HF₅, performing excitation to form a plasma, and forming a hole or groove on the wafer.

Optionally, the temperature of the etching object ranges from −30° C. to 60° C.

Optionally, the aspect ratio of the hole or groove is greater than 20.

Further, the present disclosure further provides a gas for plasma etching. The gas includes COF₂, the COF₂ can be decomposed into a COF+ group and F—, and the COF+ group can etch a dielectric material or a semiconductor material at the bottom of the hole or groove under the action of the bias radio frequency.

Optionally, the frequency of the bias radio frequency ranges from 150 kHz to 400 kHz, and the power ranges from 500 W to 10 kW.

Optionally, the aspect ratio of the hole or groove is greater than 20.

Optionally, the dielectric material includes SiO₂ or Si₃N₄; and the semiconductor material includes polycrystalline silicon.

Further, the present disclosure further provides semiconductor equipment, including:
a reaction chamber, where a reaction space is formed inside the reaction chamber to perform a plasma etching process;
a gas inlet structure, configured to introduce a process gas into the reaction space;
a base, configured to bear a wafer;
a first gas source, connected to the gas inlet structure and comprising one or more of a fluorocarbon and a hydrofluorocarbon;
a second gas source, connected to the gas inlet structure and including one or more of a carbonyl halide, an acyl halide and a carboxylic acid halide; and
a processor, configured to control the first gas source and the second gas source to introduce a reaction gas into the reaction space to perform the plasma etching process.

Optionally, the semiconductor equipment further includes a radio frequency source electrically connected to the base through a matcher.

Optionally, a cooling circulation system communicating with an interior of the base keeps the base at −80° C. to 0° C. during the etching process.

Optionally, the semiconductor equipment further includes an auxiliary gas source, where the auxiliary gas is connected to the gas inlet structure and comprises one or more of O₂, H₂, NF₃, HBr, WF₆ and Ar.

At least one of the above technical solutions has the following advantages or beneficial effects: the present disclosure provides a gas for plasma etching, and a gas combination including the gas, specifically including one or more of a carbonyl halide, an acyl halide and a carboxylic acid halide. During high-aspect-ratio etching, the gas has lower bond energy and is readily broken in one side to form a positively charged group to be accelerated to the bottom of the high-aspect-ratio structure so as to be in contact with a material at the bottom to generate an etching reaction and produce a volatile substance, thereby removing the material at the bottom. It is beneficial to deepen the depth of the hole or groove and is also beneficial to perform lateral etching at the bottom to reduce a difference between the critical dimensions of the middle part and the bottom of the high-aspect-ratio structure. The present disclosure further provides semiconductor equipment, and an etching method for plasma etching, including: providing a reaction space by a reaction chamber, and allowing two types of gases to enter the reaction space through a gas inlet structure, so that a processor operates to generate a plasma and control a charged particle or an active group to etch a wafer borne on a base, where the two types of gases respectively include one or more of a carbonyl halide, an acyl halide and a carboxylic acid halide as well as one or more of a fluorocarbon and a hydrofluorocarbon. Therefore, the collimation of the high-aspect-ratio structure on the wafer is improved.

### BRIEF DESCRIPTION OF THE DRAWINGS

In order to more clearly illustrate the technical solutions in the embodiments of the present disclosure or in the prior art, the drawings to be used in description of the embodiments or the prior art will be briefly introduced below. Obviously, the drawings in the following description are only some embodiments of the present disclosure, and those of ordinary skill in the art may obtain other drawings based on these drawings without creative work.

FIG. 1 is a schematic diagram of the change of a chemical structure when an etching gas is excited into a plasma according to an embodiment of the present disclosure;

FIG. 2 is a schematic diagram of the change of a chemical structure when an etching gas is in contact with an etching object according to an embodiment of the present disclosure;

FIG. 3 is a schematic diagram of a chemical structure according to four embodiments of the present disclosure;

FIG. 4 is a schematic diagram of three etching defects commonly occurring in the prior art;

FIG. 5 is a schematic diagram of etching morphology improvement achieved by a gas of the present disclosure;

FIG. 6 is a schematic diagram of an etching method according to the present disclosure; and

FIG. 7 is a schematic diagram of semiconductor equipment for plasma etching according to the present disclosure.

### DETAILED DESCRIPTION OF THE EMBODIMENTS

In order to make the objectives, technical solutions and advantages of the embodiments of the present disclosure clearer, the technical solutions in the embodiments of the present disclosure will be clearly and completely described below in conjunction with the drawings of the embodiments of the present disclosure. Obviously, the described embodiments are part of, but not all of, the embodiments of the present disclosure. Based on the embodiments of the present disclosure, all other embodiments obtained by those of ordinary skill in the art without creative work are included in the protection scope of the present disclosure.

In the field of plasma etching, with the increasing demand for etching a high-aspect-ratio structure, particularly in the field of 3D-NAND, however, many etching defects occur when a conventional gas or combination is used for etching, mainly focusing on the fact that the critical dimension (CD) of the etched high-aspect-ratio structure in each area does not meet the expectation, resulting in performance reduction or failure of a chip unit formed after the high-aspect-ratio structure is filled with other materials subsequently. In order to make the etched high-aspect-ratio structure meet the expectation, many methods have been explored in the industry. However, a plasma etching process relates a variety of gases, each gas plays different or overlapping roles, the gases affect each other, and the effects of other parameters such as a radio frequency, a gas pressure and a temperature will be coupled with each other, and adjusting one item will affect other items. Whether to adjust the types and flow rates of the gases or to adjust the values of other parameters, there are countless combinations. It is possible to have a slight progress in one aspect by changing one variable, but introduce a new problem in other aspects. Even if for a certain type of gas, this type of gas will play different roles during the whole process when other parameters are changed. Due to the massive results of various combinations, simple enumerative experiments without theoretical guidance cannot meet the urgent requirements for high-aspect-ratio etching.

As shown in FIG. 1, a schematic diagram of the change of a chemical structure when an etching gas is excited into a plasma, which illustrates the schematic diagram of the effect of a second type of gas according to the present disclosure, taking COF₂ as an example, due to the existence of a carbon-oxygen double bond, a chemical bond between carbon and fluorine has relatively low bond energy; when the COF₂ gas is excited to form a plasma under the radio frequency energy with a certain power, the single bond between carbon and fluorine is more likely to break; furthermore, according to the currently coupled radio frequency energy, the carbon-fluorine single bond on one side is broken and the carbon-fluorine single bond on the other side remains, a positively charged group including carbon, oxygen and fluorine as well as a negatively charged fluorion are generated; and the positively charged group is more likely to move in a certain direction under the action of a directional bias radio frequency electric field, thereby providing conditions for the positively charged group to arrive at the bottom along the high-aspect-ratio structure by setting the bias radio frequency.

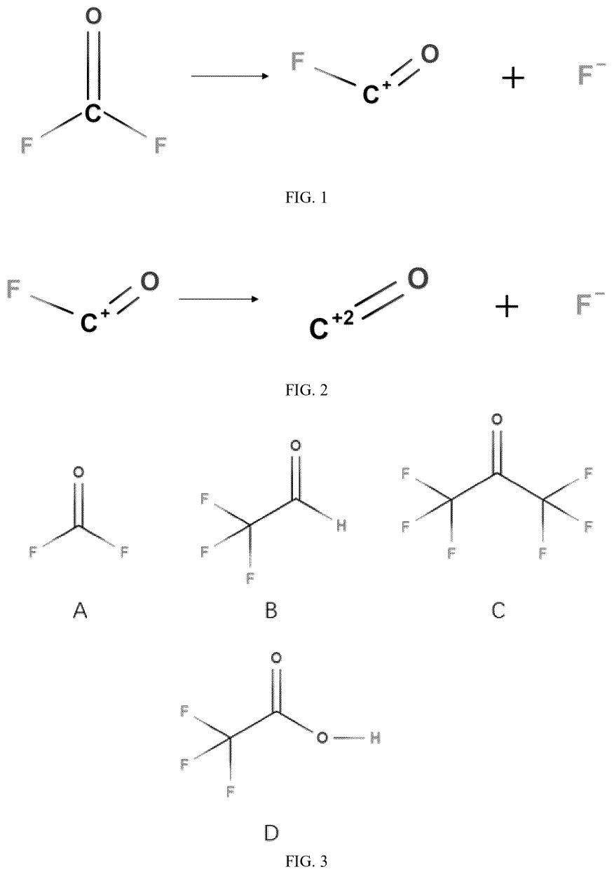

As shown in FIG. 2, a schematic diagram of the change of a chemical structure when an etching gas is in contact with an etching object according to an embodiment of the present disclosure, the positively charged group will perform a chemical reaction with a material to be etched when arriving at the bottom of the high-aspect-ratio structure. Specifically, another carbon-fluorine single bond of COF+ is broken to release the fluorion to react with the material to be etched to generate a volatile substance to be discharged, thereby continuously etching the high-aspect-ratio structure.

In some other embodiments, the etching gas is not limited to COF₂, and other compound gases with a carbon-oxygen double bond capable of reducing the bond energy of the group and with a halogen element capable of etching a medium can achieve the same technical effect. Specifically, the gas may be a carbonyl halide, an acyl halide and a carboxylic acid halide, where the carbonyl has two single bonds with low bond energy, so both the two single bonds can be combined with one of the following functional groups: F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—; and the aldehyde and the carboxyl have only one low-energy single bond, so the single bond can be combined with one of the following functional groups: F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—. As shown in FIG. 3, in some embodiments, etching gases that can be selected are as follows: an etching gas A: COF₂; an etching gas B: CF₃CHO; an etching gas C: CO(CF₃)2; and an etching gas D: CF₃COOH.

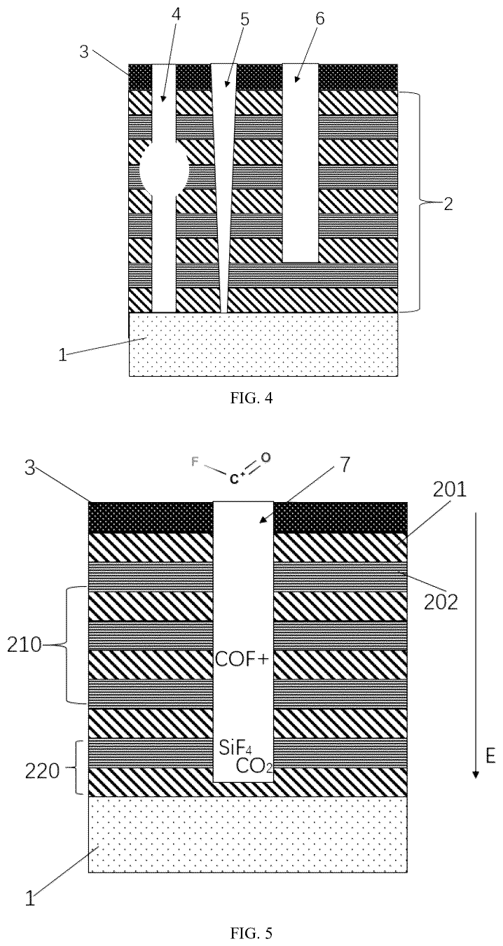

As shown in FIG. 4, a schematic diagram of three etching defects commonly occurring in the prior art, usually, a wafer as an etching object includes a substrate 1, a layer 2 to be etched, and a mask layer 3 with a pattern on the layer 2 to be etched. When it is necessary to increase the thickness of the etched layer 2 to be etched so as to increase the aspect ratio of an etched target structure such as a hole or groove, some typical defects will occur. Taking the hole as an example, for a curved hole 4, the etching degree of a middle part is greater than that of other parts, thereby leading to a curved side wall of the middle part and destroying the vertical collimation of an ideal hole; for an inclined hole 5, the quantity of an etching substance that can arrive at the bottom is far less than the quantity of the etching material that can arrive at the upper part and the middle part, thereby leading to a wedge shape with a wide upper part and a narrow lower part and destroying the vertical collimation of the ideal hole; and for a short hole 6, the etching substance cannot arrive at the bottom and only can continuously perform lateral etching, so that the aspect ratio dimension of the ideal hole cannot be reached. For the ideal hole, the etching substance can continue to downward etch the substance to be etched along the dimension of a mask 3, only a small amount of lateral etching occurs, and a consistent high-aspect-ratio hole is finally obtained. The above defects are all caused by the fact that the etching substance cannot perform longitudinal etching according to a set speed or degree.

FIG. 5 is a schematic diagram of etching morphology improvement achieved by a gas of the present disclosure. A wafer to be etched includes a substrate 1 and a layer to be etched located above the substrate 1, where the substrate may be made of a Si material in some embodiments; the layer to be etched may be a dielectric material or a semiconductor material, or a stack of many materials, or a doped mixture, for example, single-layer SiO₂, Si₃N₄ or polycrystalline silicon, as well as an alternating stack of SiO₂ and Si₃N₄, and an alternating stack of SiO₂ and polycrystalline silicon; and optionally, in some embodiments, the layer to be etched includes an alternating stack of a SiO₂ layer 201 and a Si₃N₄ layer 202. Under the action of a downward electric field E formed by the bias radio frequency, most of positively charged COF+ groups move downward to a bottom 220 along a hole 7 and then perform the following reactions:

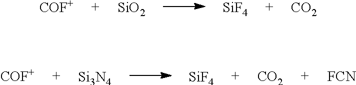

Under the condition of the reaction space, SiF₄, CO₂ and FCN are all gases that can be pumped away from the hole 7 to continuously etch the hole 7 to form the structure of the high-aspect-ratio hole 7. Since COF+ has good directivity controlled by the electric field, under the condition that the etching dimension is restricted by the mask layer, most of the COF+ passing through an opening of the hole 7 will continue to travel downward, will not be consumed on a side wall of a middle part 210 of the hole 7 and will arrive at the bottom 220. Furthermore, compared with the dimension of the mask layer, the redundant material to be etched will be etched away by the COF+. Since the middle part 210 is located at a shallow position of the hole 7, a group playing an etching role is easier to arrive, and the dimension of the middle part 210 is closer to the defined dimension of the mask. The bottom 220 is located at a deep position of the hole 7, a conventional etching gas is difficult to arrive through free diffusion, so the material at the bottom 220 is etched incompletely, and the dimension of the bottom 220 is far less than the defined dimension of the mask. According to the present disclosure, most of the COF+ groups decomposed by the COF₂ gas can be pushed to the bottom 220 by an electric field force. Furthermore, the COF+ group easily releases another F ion when in contact with the material at the bottom 220, the F ion performs etching reaction with the material at the bottom 220 to enlarge a lateral opening of the bottom, and lateral etching does not occur at the middle part 210, so the lateral etching degree of the COF+ at the bottom 220 is greater than the lateral etching degree at the middle part 210, thereby avoiding the curved hole 4 and the inclined hole 5 in FIG. 4.

In some embodiments, the gas combination for plasma etching includes one or more of the carbonyl halide, the acyl halide and the carboxylic acid halide as the second type of gas, and further includes one or more of a fluorocarbon and a hydrofluorocarbon as a first type of gas. The ratio of the first type of gas to the second type of gas can be adjusted to obtain an appropriate etching result. Specifically, the first type of gas may include one or more of CF₄, CHF₃, CH₂F₂, C₂HF₅ and C₃HF₅ In some other embodiments, the gas combination may further include one or more of O₂, H₂, NF₃, HBr, WF₆ and Ar as an auxiliary gas.

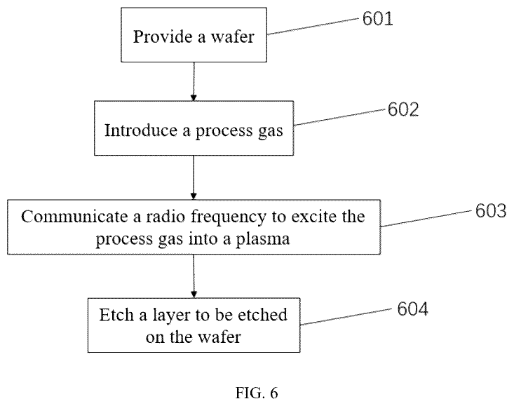

The present disclosure further provides a plasma etching method, as shown in FIG. 6, specifically including:

Step 601: provide a wafer. A layer to be etched, as an etching object, is arranged on the wafer, and may be SiO₂, Si₃N₄ or an alternating stack of the two. A mask layer for restricting an etching result is arranged on the layer to be etched, and may be a material such as amorphous carbon with a high etching selection ratio relative to the layer to be etched. In some embodiments, the layer to be etched may have a shallow hole or a shallow groove that has been etched by the previous step, or may be an untreated complete layer thereon.

Step 602: introduce a process gas. The process gas includes a second type of gas, for example, one or more of a carbonyl halide, an acyl halide and a carboxylic acid halide. In some embodiments, the second type of gas may be COF₂, COCl₂, COBr₂, COI₂, (CF₃)—CO—H, (CF₃)CO—F, (CF₃)—CO—Cl, (CF₃)—CO—OH, (CF₃)—CO—(CF₃) and (CF₃)—CO—O—CO—(CF₃). The layer to be etched is etched by the second type of gas until a hole or groove with a predetermined aspect ratio. The flow rate of the second type of gas ranges from 10 sccm to 200 sccm.

According to the selection of an etching object, the process gas may further include a first type of gas, for example, one or more of a fluorocarbon and a hydrofluorocarbon. In some embodiments, the first type of gas may be CF₄, CHF₃, CH₂F₂, C₂HF₅, C₃HF₅ or a combination of the above. The first type of gas may etch the layer to be etched and protect a side wall of the high-aspect-ratio hole or groove. The flow rate of the first type of gas ranges from 10 sccm to 300 sccm.

In some other embodiments, the process gas may further include an auxiliary gas, for example, O₂ and NF₃ capable of avoiding blockage caused by too much polymer deposited at the top of the hole or groove, H₂ capable of improving the selection ratio of the mask to the layer to be etched, and HBr and WF₆ capable of enhancing the protection of the side wall of the hole or groove to prevent the side wall from being curved. The flow rate of the auxiliary gas ranges from 1 sccm to 200 sccm.

In some embodiments, the volume of the first type of gas accounts for 30% to 70% of the volume of the total gas, and the volume of the second type of gas accounts for 1% to 30% of the volume of the total gas. The volume of the auxiliary gas accounts for 10% to 30% of the volume of the total gas. The first type of gas accounts for most of the total gas and plays a major role in etching. The second type of gas modifies the defective high-aspect-ratio structure etched by the first type of gas, so that the structure has a CD as consistent as possible in an up-and-down direction.

Step 603: communicate a radio frequency to excite the process gas into a plasma. The concentration of the charged particles or active species in the plasma can be controlled by selecting an appropriate radio frequency, thereby adjusting the etching rate. In order to achieve a predetermined etching result under the condition of the gas combination of the present disclosure, the frequency of the radio frequency generating the plasma ranges from 13 MHz to 200 MHz, and the power ranges from 1000 w to 30000 w. The radio frequency generating the plasma is required to ensure that the gas can be ionized and too high power which brings danger to the process reaction cannot be output.

Step 604: etch a layer to be etched on the wafer. In this step, the energy of the bias radio frequency is loaded into the plasma in the reaction space, and the radio frequency can provide a directional electric field, so that the charged particle capable of etching the layer to be etched enters the hole or groove, and an appropriate etching rate is maintained, thereby keeping the up-and-down CD of the hole or groove consistent. The frequency of the used bias radio frequency ranges from 150 kHz to 4 MHz, and the power ranges from 1 kW to 10 kW. Finally, the hole or groove with a high-aspect-ratio structure is formed in the layer to be etched, the range of the aspect ratio is greater than 20, and in some embodiments, the range of the aspect ratio is greater than 40. The frequency of the bias radio frequency is required to ensure that the COF+ group can arrive at the bottom.

To maintain the plasma and discharge reaction byproducts in time, it is necessary to continuously evacuate the reaction space to maintain a certain gas pressure, and the gas pressure ranges from 15 mT to 40 mT. In order to make the generated polymer protect the side wall of the hole or groove to prevent excessive lateral etching while avoiding the blockage of the etching channel caused by too much accumulation, it is necessary to control the temperature of the wafer at −50° C. to 100° C. In some embodiments, the temperature of the wafer is 0° C. to 10° C.

In some embodiments, the etching object with the complete layer to be etched can be etched by the first type of gas and the second type of gas until the high-aspect-ratio hole or groove meeting the target is formed. In some other embodiments, the layer to be etched can be etched in two stages; in the first stage, a shallow hole or groove is etched by preliminary treatment, for example, the first type of gas is used to cooperate some types of auxiliary gases; since the first type of gas has a higher proportion of fluorine content, a higher etching rate can be ensured; at this time, since the depth of the hole or groove of the layer to be etched is small, the etching gas can easily arrive at the bottom of the hole or groove, and the problem shown in FIG. 4 is avoided; and in the second stage, the shallow hole or groove is continuously etched by the gas combination including the second type of gas until the high-aspect-ratio of hole or groove meeting the target is formed, thereby ensuring a high etching rate and a good etching morphology.

Parameters and etching results of some embodiments are listed below by taking the layer to be etched with SiO₂ and Si₃N₄ alternately stacked as an etching object under the condition that the temperature of the base is −60° C.

### Comparative Example 1

| | Flow Rate | Gas | Aspect | Middle Part | Bottom CD |
|---|---|---|---|---|---|
| Gas Type | (sccm) | Pressure | Ratio | CD (nm) | (nm) |
| H₂ | 100 | 30 | 40 ± 2 | 105 ± 5 | 50 ± 5 |
| CF₄ | 150 | | | | |
| NF₃ | 10 | | | | |
| HBr | 25 | | | | |
| Ar | 50 | | | | |

Taking the above situation as an example, under the condition that the first type of gas is CF₄ and the auxiliary gases are H₂, NF₃, HBr and Ar, when etching is performed to the aspect ratio about 40, the difference between the middle part CD and the bottom CD reaches 45 nm, which apparently does not meet the requirement of the final result.

### Embodiment 1

| | Flow Rate | Gas | Aspect | Middle Part | Bottom CD |
|---|---|---|---|---|---|
| Gas Type | (sccm) | Pressure | Ratio | CD (nm) | (nm) |
| H₂ | 100 | 30 | 50 ± 2 | 100 ± 5 | 60 ± 5 |
| CF₄ | 150 | | | | |
| COF₂ | 10 | | | | |
| NF₃ | 10 | | | | |
| HBr | 25 | | | | |
| Ar | 50 | | | | |

Under the same other conditions as in Comparative Example 1, COF₂ of 10 sccm is added as the second type of gas. It can be seen that even if the aspect ratio is increased to about 50, the CD difference between the middle part and the bottom is improved and reduced to about 40 nm.

### Embodiment 2

| | Flow Rate | Gas | Aspect | Middle Part | Bottom CD |
|---|---|---|---|---|---|
| Gas Type | (sccm) | Pressure | Ratio | CD (nm) | (nm) |
| H₂ | 100 | 30 | 54 ± 2 | 100 ± 5 | 70 ± 5 |
| CF₄ | 150 | | | | |
| COF₂ | 30 | | | | |
| NF₃ | 10 | | | | |
| HBr | 25 | | | | |
| Ar | 50 | | | | |

Under the same other conditions as in Embodiment 1, the flow rate of COF₂ is continuously increased to 30 sccm. It can be seen that even if the aspect ratio is continuously increased, the CD difference between the middle part and the bottom is continuously improved to 30 nm.

### Embodiment 3

| | Flow Rate | Gas | Aspect | Middle Part | Bottom CD |
|---|---|---|---|---|---|
| Gas Type | (sccm) | Pressure | Ratio | CD (nm) | (nm) |
| H₂ | 100 | 30 | 55 ± 2 | 100 ± 5 | 80 ± 5 |
| CF₄ | 150 | | | | |
| COF₂ | 70 | | | | |
| NF₃ | 10 | | | | |
| HBr | 25 | | | | |
| Ar | 50 | | | | |

Under the same other conditions as in Embodiment 1, the flow rate of COF₂ is continuously increased to 70 sccm. It can be seen that the CD difference between the middle part and the bottom is continuously improved to 20 nm under the condition that the aspect ratio is basically unchanged.

### Embodiment 4

| | Flow Rate | Gas | Aspect | Middle Part | Bottom CD |
|---|---|---|---|---|---|
| Gas Type | (sccm) | Pressure | Ratio | CD (nm) | (nm) |
| H₂ | 100 | 30 | 55 ± 2 | 100 ± 5 | 85 ± 5 |
| CF₄ | 150 | | | | |
| COF₂ | 100 | | | | |
| NF₃ | 10 | | | | |
| HBr | 25 | | | | |
| Ar | 50 | | | | |

Under the same other conditions as in Embodiment 1, the flow rate of COF₂ is continuously increased to 100 sccm. It can be seen that the CD difference between the middle part and the bottom is further improved to about 15 nm under the condition that the aspect ratio is basically unchanged, but relative to the increased quantity of COF₂, the benefit ratio has been significantly reduced.

Through comparative experiments, a small amount of COF₂ can improve the morphology of the high-aspect-ratio structure, and when the flow rate of COF₂ is controlled at 20 sccm to 70 sccm, or the volume ratio is within the range of 1% to 30%, the improvement effect can achieve benefit maximization relative to the use amount.

According to an etching gas and a combination thereof, an etching method and an etching device of the present disclosure, one or more of a carbonyl halide, an acyl halide and a carboxylic acid halide serves as a reaction gas, and this type of gas has a double bond of carbon (C) and oxygen (O). Due to the existence of the O atom on the double bond, other halogen-containing groups or halogen atoms combined with C are easier to break away from the bondage of C. when certain radio frequency energy is applied, one of the halogen-containing groups or halogen atoms is first separated to change the gas atoms into positively charged groups, the positively charged groups are accelerated to the bottom of the high-aspect-ratio structure more easily by the radio frequency electric field and react with the material to be etched at the bottom, thereby removing the material at the bottom. The groups perform lateral etching on the bottom to achieve the consistency of the up-and-down critical dimension (CD) of the high-aspect-ratio structure.

The second type of gas of the present disclosure mainly includes a halogen gas containing a carbon-oxygen double bond. Different from the use of the gas as an oxidizing gas, it is creatively found in the present disclosure that the gas can easily separate one of the fluorions into charged COF+ during plasma dissociation. When a bias radio frequency power supply is applied to the wafer to be etched, the charged COF+ group can arrive at the bottom of the etching hole or groove under the action of the bias radio frequency electric field and can release another fluorion to participate in the etching reaction when in contact with the material at the bottom 220. Therefore, the CD of the bottom of the hole or groove is greatly increased, the difference between the CD of the bottom and the CD of the middle part is reduced, and the perpendicularity of the side wall of the etching hole or groove is improved. In particular, for the etching structure with a high aspect ratio, there is a problem that the CD of the bottom opening is gradually reduced beyond a certain depth, and the gas disclosed by the present disclosure has unexpected effects.

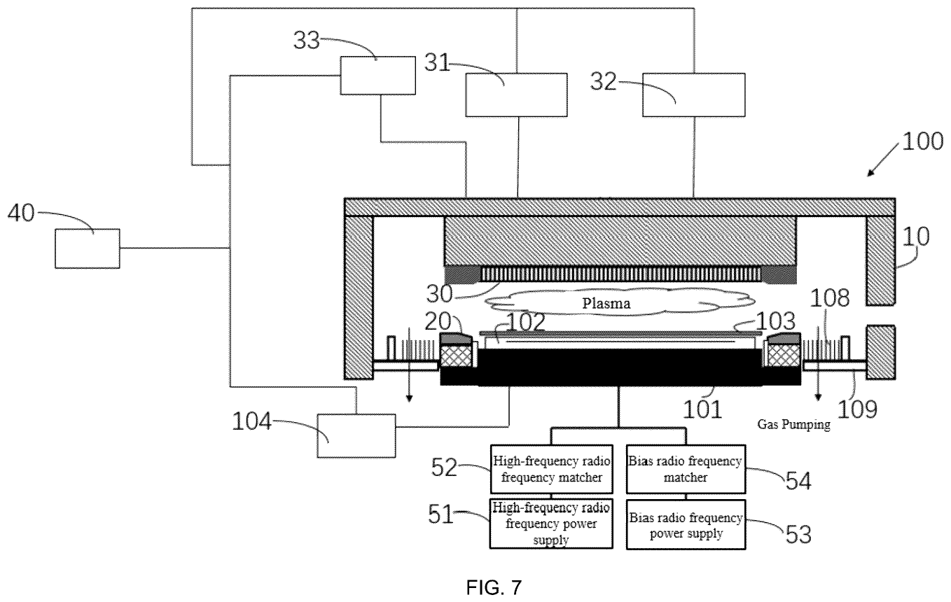

The present disclosure further discloses semiconductor equipment 100 for plasma etching. As shown in FIG. 7, the semiconductor equipment specifically includes a reaction chamber 10, where a reaction space is formed inside the reaction chamber to perform a plasma etching process;
a gas inlet structure 30, configured to introduce a process gas into the reaction space; a base 101, configured to bear a wafer 103, where the base 101 includes an electrostatic chuck 102, the wafer 103 can be clamped by electrostatic attraction, an edge ring 20 surrounds the base 101 and can enlarge the range of a lower electrode to etch the wafer 103 more uniformly, a confinement ring 108 is arranged between the edge ring 20 and a side wall of the reaction chamber 10, a gas pump is arranged below the confinement ring 108 and pumps out the redundant gas and reaction byproducts in the reaction space, the confinement ring 108 can avoid damage to the structure by the discharge phenomenon of the plasma entering the lower gas pumping space during gas pumping, and a grounding ring 109 is in contact connection with a part below the confinement ring 108 and configured to achieve a complete loop of the radio frequency inside the reaction chamber 10;
a first gas source 31, connected to the gas inlet structure 30, where the first gas source 31 includes one or more of a fluorocarbon and a hydrofluorocarbon; a second gas source 32, connected to the gas inlet structure 30, where the second gas source 32 includes one or more of a carbonyl halide, an acyl halide and a carboxylic acid halide; an auxiliary gas source 33, connected to the gas inlet structure 30, where the auxiliary gas source includes one or more of O2, H2, NF3, HBr and WF6; and
a processor 40, configured to control the first gas source 31, the second gas source 32 and the auxiliary gas source 33 through an electronic circuit and a flow controller to introduce a reaction gas into the reaction space to perform a plasma etching process.

The semiconductor equipment further includes a radio frequency source electrically connected to the base 101 through a matcher. The radio frequency source may specifically include: a high-frequency radio frequency power supply 51, configured to generate a plasma and electrically connected to the base 101 through a high-frequency radio frequency matcher 52; and a bias radio frequency power supply 53, configured to control the moving direction of the charged group and electrically connected to the base 101 through a bias radio frequency matcher 54.

To control the temperature of the wafer 103, a cooling circulation system 104 communicating with the interior of the base 101, such as a cooling circulation pipeline with a cooling fluid, can also set parameters through the processor 40, so that the temperature of the base 101 can be maintained at −80° C. to 0° C. during the etching process.

The plasma etching method disclosed by the present disclosure is not limited to being applied to a plasma processing apparatus in the above embodiments, and is also applicable to other plasma processing apparatuses, and the details are not elaborated here.

Although the content of the present disclosure has been described in detail through the aforementioned preferred embodiments, it should be recognized that the above description should not be considered as limiting the present disclosure. Various modifications and alternatives to the present disclosure will become apparent to those skilled in the art upon reading the foregoing disclosure. Accordingly, the protection scope of the present disclosure shall be limited by the appended claims.

1. A plasma etching method, comprising the following steps:
providing a wafer with a layer to be etched and a mask layer above the layer to be etched thereon; and
introducing a first type of gas and a second type of gas and performing excitation to form a plasma to etch a layer to be etched to form a hole or groove,
wherein the first type of gas comprises one or more of a fluorocarbon and a hydrofluorocarbon, and
the second type of gas comprises one or more of a carbonyl halide, an acyl halide and a carboxylic acid halide.

2. The plasma etching method according to claim 1, wherein the carbonyl halide comprises a functional group (CO)— in combination with one or two of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

3. The plasma etching method according to claim 1, wherein the acyl halide comprises a functional group (COH)— in combination with one of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

4. The plasma etching method according to claim 1, wherein the carboxylic acid halide comprises a functional group (COOH)— in combination with one of functional groups F—, Cl—, Br—, I—, CF₃—, CHF₂—, CH₂F—, CCl₃—, CHCl₂—, CH₂Cl—, CBr₃—, CHBr₂—, CH₂Br—, CI₃—, CHI₂— and CH₂I—.

5. The plasma etching method according to claim 1, wherein the second type of gas comprises COF₂.

6. The plasma etching method according to claim 5, wherein the first type of gas comprises one or more of CF₄, CHF₃, CH₂F₂, C₂HF₅ and C₃HF₅.

7. The plasma etching method according to claim 6, wherein the volume of the first type of gas accounts for 30% to 70% of the volume of the total gas, and the volume of the second type of gas accounts for 1% to 30% of the volume of the total gas.

8. The plasma etching method according to claim 1, wherein when the first type of gas and the second type of gas are introduced, an auxiliary gas is also introduced, and the auxiliary gas comprises one or more of O₂, H₂, NF₃, HBr, WF₆ and Ar.

9. The plasma etching method according to claim 8, wherein the volume of the auxiliary gas accounts for 10% to 30% of the volume of the total gas.

10. The plasma etching method according to claim 1, wherein the layer to be etched comprises SiO₂, Si₃N₄, polycrystalline silicon or an alternating stack of any two of the aforementioned.

11. The plasma etching method according to claim 1, wherein the aspect ratio of the hole or groove is greater than 40.

12. The plasma etching method according to claim 1, wherein when the layer to be etched is etched, the temperature of the wafer ranges from −50° C. to 100° C.

13. A plasma etching method, comprising the following steps:
providing an etching object with a hole or groove structure thereon; and
providing a process gas comprising COF₂, performing excitation to form a plasma, and continuously etching the hole or groove by applying a bias radio frequency.

14. The etching method according to claim 13, wherein when the COF₂ is excited into the plasma, the COF₂ is capable of being decomposed into a COF+ group and F—, the COF+ group arrives at the bottom of the hole or groove under the action of the bias radio frequency and performs a chemical reaction with the etching object at the bottom of the hole or groove to generate a volatile product.

15. The etching method according to claim 14, wherein the lateral etching quantity of the COF+ group at the bottom of the hole or groove is greater than the lateral etching quantity of the COF+ group at the middle part of the hole or groove.

16. The etching method according to claim 13, wherein the etching object comprises SiO₂, Si₃N₄, polycrystalline silicon or an alternating stack of any two of the above.

17. The plasma etching method according to claim 13, further comprising the following steps:
providing a wafer with a layer to be etched and a mask layer above the layer to be etched thereon, wherein the layer to be etched comprises SiO₂, Si₃N₄ or an alternating stack of the two; and
providing a process gas comprising one or more of CF₄, CHF₃, CH₂F₂, C₂HF₅ and C₃HF₅, performing excitation to form a plasma, and forming a hole or groove on the wafer.

18. The etching method according to claim 13, wherein the temperature of the etching object ranges from −30° C. to 60° C.

19. Semiconductor equipment, comprising:
a reaction chamber, wherein a reaction space is formed inside the reaction chamber to perform a plasma etching process;
a gas inlet structure, configured to introduce a process gas into the reaction space;
a base, configured to bear a wafer;
a first gas source, connected to the gas inlet structure and comprising one or more of a fluorocarbon and a hydrofluorocarbon;
a second gas source, connected to the gas inlet structure and comprising one or more of a carbonyl halide, an acyl halide and a carboxylic acid halide; and
a processor, configured to control the first gas source and the second gas source to introduce a reaction gas into the reaction space to perform the plasma etching process.

20. The semiconductor equipment according to claim 19, further comprising a radio frequency source electrically connected to the base through a matcher.

21. The semiconductor equipment according to claim 19, wherein a cooling circulation system communicating with an interior of the base keeps the base at −80° C. to 0° C. during the etching process.

22. The semiconductor equipment according to claim 19, further comprising an auxiliary gas source, wherein the auxiliary gas is connected to the gas inlet structure and comprises one or more of O₂, H₂, NF₃, HBr, WF₆ and Ar.
